(19) United States
(12) Patent Application Publication
(10) Pub. No.: US 2013/0323422 A1
(43) Pub. Date: Dec. 5, 2013

(54) Apparatus for CVD and ALD with an Elongate Nozzle and Methods Of Use

(71) Applicant: Igor Peidous, Loudonville, NY (US)

(72) Inventor: Igor Peidous, Loudonville, NY (US)

(73) Assignee: Applied Materials, Inc., Santa Clara, CA (US)

(21) Appl. No.: 13/482,552

(22) Filed: May 29, 2012

(51) Int. Cl. C23C 16/458; C23C 16/455; C23C 16/46

(52) U.S. Cl. 427/255.7; 118/728; 118/729; 118/725; 118/730; 118/719

(57) ABSTRACT

Provided are atomic layer deposition apparatus and methods including a processing chamber with a substrate support at least one elongate nozzle movable relative to the substrate support. The processing chamber has a first gas at a first pressure and a second gas is provided from the elongate nozzle at a second pressure greater than the first pressure.

### BACKGROUND

Embodiments of the invention relate to methods and apparatus for chemical vapor deposition (CVD) of thin films which may be used for manufacturing electronic devices such as semiconductors, flat panel displays, photovoltaic panels and such.

CVD is a chemical process used to produce high-purity, high-performance solid materials. In a typical CVD process, the wafer (substrate) is exposed to one or more volatile precursors, which react and/or decompose on the substrate surface. In the result, a desired film is deposited. During the film deposition, volatile by-products are also produced and concurrently removed by the gas flow through the reaction chamber.

CVD methods are widely used in the semiconductor industry. However, due to limitations in the control over deposition rates, conventional implementations of CVD may not be applicable for depositing extremely thin films. Another CVD challenge is depositing films with high within-wafer uniformity. This drawback will be especially critical with the transition of semiconductor manufacturers to 450 mm wafers.

The methods of atomic layer deposition (ALD) overcome some limitations of conventional CVD. ALD is used for depositing extremely thin films which become increasingly important in advanced microelectronic manufacturing. ALD enables continues device scaling as well as emerging semiconductor hetero-structural and 3D device architectures. ALD is used for forming gate oxides (Al₂O₃, TiO₂, SnO₂, ZrO₂, HfO₂), metal gates, copper diffusion barriers (TiN, TaN, WN), and other applications which benefit from the control over film deposition at the atomic scale.

ALD is based on implementing a series of alternate self-limiting surface reactions on substrates. Usually, a substrate is sequentially exposed to different gas phase chemicals (precursors). Each precursor reacts with the substrate surface forming an atomic scale layer on top of the previously formed atomic layer. In some cases, deposition cycles that modify the previously deposited atomic layers or remove undesired chemical groups from the previously deposited atomic layers may be used. By applying alternate precursors to the surface repeatedly, a thin film is deposited.

The growth of material layers by ALD is often conducted in reaction chambers by repeating reaction cycles. Each of these reaction cycles includes two steps: (i) a substrate is exposed to a precursor; (ii) non-reacted precursor and the gaseous reaction by-products are removed from the chamber by purging or evacuation. Subsequent reaction cycles may use alternate precursors. To grow a film of a desired thickness, reaction cycles are repeated as many times as required.

For example, U.S. Pat. No. 7,838,084 describes ALD methods of depositing an oxide on a substrate comprising: (i) chemisorbing a first species onto a substrate to form a first species monolayer onto the substrate from a gaseous precursor, the first species monolayer being at least substantially saturated; (ii) contacting the chemisorbed first species with a remote oxygen and nitrogen plasma effective to react with the first species to form a monolayer that is at least substantially saturated and comprises an oxide of a component of the first species monolayer; (iii) successively repeating the chemisorbing and the contacting with remote plasma oxygen and plasma nitrogen effective to form porous oxide on the substrate.

Another example is presented by U.S. Pat. No. 7,923,070 that describes an atomic layer deposition method of forming a conductive metal nitride layer comprising (i) providing a substrate within a deposition chamber; (ii) chemisorbing a first species to form a first species monolayer onto the substrate from a gaseous first precursor comprising an amido (or imido) metal organic compound, the first species monolayer comprising organic groups; (iii) contacting the chemisorbed first species with a hydrogen containing second precursor effective to react with the first species monolayer to remove organic groups from the first species monolayer; (iv) successively repeating said chemisorbing and contacting under conditions effective to form a layer of material on the substrate comprising a conductive metal nitride.

A general advantage of ALD is that it may provide highly conformal films with good thickness uniformity because of the surface controlled self-terminating ALD reactions. A general disadvantage of conventional ALD processes is their slowness. Only one atomic monolayer, or even its fraction, may be deposited in one reaction cycle. Then, a significant time is required for purging or evacuating the non-reacted precursor and reaction by-products from the deposition chambers.

Even though ALD processes are based on self-terminating reactions, the parameters of deposited layers are sensitive to, for example, precursor concentrations, partial pressure in the gaseous phase and the precursor exposure time. Therefore, to obtain ALD films of high uniformity, a careful introduction and stabilization of precursor distributions in the deposition chambers are desired, which can be difficult to achieve. Equalization of precursor partial pressures in chambers also leads to an essential delay of every ALD cycle.

Another drawback of ALD is the relatively high impurity content in the deposited films. It is associated with incomplete precursor reactions, adsorption of the reaction species and their subsequent incorporation into the growing films.

There is an ongoing need in the art for improved apparatuses and methods for processing substrates by atomic layer deposition.

### SUMMARY

One or more embodiments of the invention are directed to deposition systems comprising a processing chamber, a gas inlet, a substrate support and an elongate nozzle. The gas inlet is to provide a first gas at a first pressure to the processing chamber. The substrate support is disposed within the processing chamber to support a substrate. The elongate nozzle is to provide a second gas at a second pressure to the processing chamber. The elongate nozzle is adjacent the substrate support. The second pressure is higher than the first pressure. At least one of the elongate nozzle and the substrate support is movable relative to the other one of the elongate nozzle and the substrate support.

In some embodiments, when a substrate is present, movement of the elongate nozzle covers the entire surface of the substrate. In one or more embodiments, when a substrate is present, the elongate nozzle has a width greater than that of the substrate.

In some embodiments, the substrate support is in a substantially fixed position and the elongate nozzle moves. In one or more embodiments, the elongate nozzle is in a substantially fixed position and the substrate support moves.

In some embodiments, the substrate support comprises a heater. In one or more embodiments, the substrate support rotates either continuously or in discrete steps.

In some embodiments, when a substrate is present, the elongate nozzle is in the range of about 0.5 mm to about 10 mm from the substrate.

In one or more embodiments, the elongate nozzle moves relative to the substrate support at a speed in the range of about 10 mm/sec to about 1 m/sec.

In some embodiments, the first gas and the second gas are reactive gases.

Additional embodiments of the invention further comprise a second elongate nozzle to provide a third gas at a pressure greater than the first pressure to the processing chamber. In some embodiments, the substrate support is in a substantially fixed position and each elongate nozzle is independently movable. In one or more embodiments, the first gas is an inert gas and each of the second gas and third gas are different reactive gases. In some embodiments, each of the first gas, the second gas and the third gas are different reactive gases.

One or more embodiments of the invention are directed to cluster tools comprising a central transfer chamber and the atomic layer deposition system described.

Further embodiments of the invention are directed to atomic layer deposition systems comprising a processing chamber, a gas inlet, a substrate support, a first elongate nozzle and a second elongate nozzle. The gas inlet is to provide a first gas at a first pressure to the processing chamber. The substrate support is disposed within the processing chamber to support a substrate in a substantially fixed position. The first elongate nozzle is to provide a second gas at a second pressure toward the substrate support in the processing chamber. The first elongate nozzle is movable relative to the substrate support. The second pressure is higher than the first pressure. The second elongate nozzle is to provide a third gas toward the substrate support in the processing chamber. The second elongate nozzle is independently movable relative to the substrate support and the first elongate nozzle.

Additional embodiments of the invention are directed to methods of processing a substrate in a processing chamber. The substrate is supported on a substrate support. The substrate is exposed to a first gas in the processing chamber. A first elongate nozzle is moved relative to and above the substrate support. The first elongate nozzle providing a second gas to the processing chamber toward the substrate. The first elongate nozzle moves reciprocally relative to the substrate so that portions of the substrate under the first elongate nozzle are exposed to the second gas and portions of the substrate not under the first elongate nozzle are exposed to the first gas.

Some embodiments further comprise moving a second elongate nozzle relative to and above the substrate support. The second elongate nozzle providing a third gas to the processing chamber toward the substrate. The second elongate nozzle adjacent to the first elongate nozzle and independently movable relative to the first elongate nozzle and the substrate.

In some embodiments, the first gas is an inert gas and each of the second gas and third gas are different reactive gases. In one or more embodiments, each of the first gas, the second gas and the third gas are different reactive gases.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic side view of an atomic layer deposition chamber according to one or more embodiments of the invention;

FIG. 2 shows a top view of an atomic layer deposition chamber in accordance with one or more embodiments of the invention;

FIG. 3 show a partial side view of an atomic layer deposition chamber in accordance with one or more embodiments of the invention;

FIG. 4 show a partial top view of atomic layer deposition chamber in accordance with one or more embodiments of the invention;

FIG. 5 shows a partial side view of an atomic layer deposition chamber in accordance with one or more embodiments of the invention;

FIG. 6 shows a partial side view of an atomic layer deposition chamber in accordance with one or more embodiments of the invention;

FIG. 7 shows a partial side view of an atomic layer deposition chamber in accordance with one or more embodiments of the invention;

FIG. 8 shows a partial side view of an atomic layer deposition chamber in accordance with one or more embodiments of the invention;

FIG. 9 shows a partial side view of an atomic layer deposition chamber in accordance with one or more embodiments of the invention;

FIG. 10 shows partial a side view of an atomic layer deposition chamber in accordance with one or more embodiments of the invention;

FIG. 11 shows a partial side view of an atomic layer deposition chamber in accordance with one or more embodiments of the invention;

FIG. 12 shows a partial side view of an atomic layer deposition chamber in accordance with one or more embodiments of the invention; and

FIG. 13 shows a schematic of a cluster tool in accordance with one or more embodiment of the invention.

### DETAILED DESCRIPTION

Embodiments of the present invention provide apparatus and CVD method that enables an enhanced control over film deposition, in particular on substrates of large size such as 450 mm wafers. The apparatus and method may be used in ALD regime that improves film uniformity and reduces film contamination while allowing high throughput compared to conventional methods of ALD.

As used in this specification and the appended claims, the terms “wafer” and “substrate” have essentially the same meaning and are used interchangeably.

As used in this specification and the appended claims, the terms “precursor”, “reactive gas” and the like are used interchangeably. It will be understood by those skilled in the art that use of the term “precursor” does not limit the invention to reactants which are predecessors to a film, but can also include reactants which may be used to etch a substrate or film. Use of “first gas” and the like may refer to either reactive or inert gases depending on the context.

The term “substrate surface” means the bare surface of a substrate (e.g., a silicon wafer) or a layer deposited on the bare surface of the substrate. For example, if a substrate has a uniform dielectric film on the surface, and it is said that the substrate is exposed to a precursor, it will be understood that the film on the surface is exposed to the precursor.

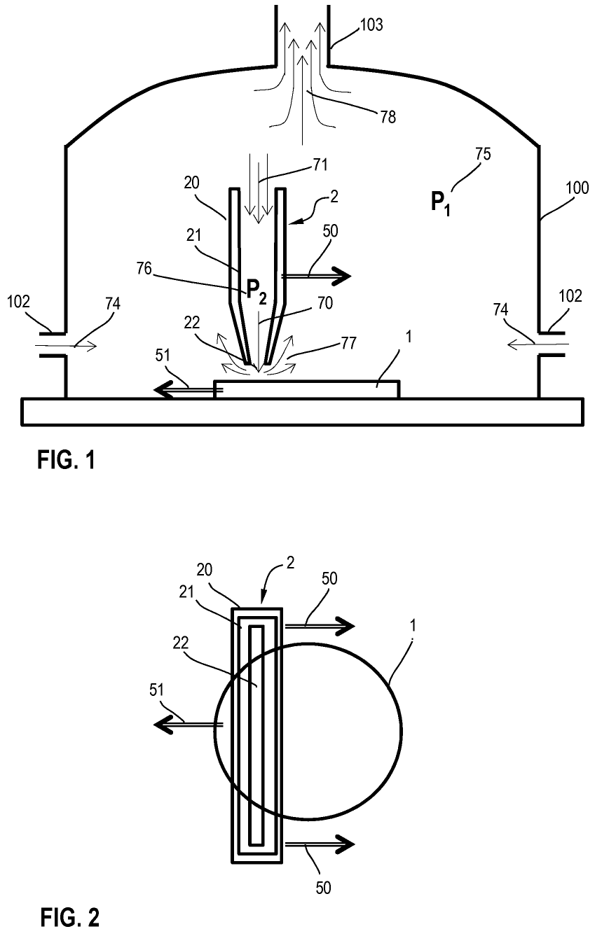

One embodiment of the invention is presented in FIG. 1. A substrate 1, on the surface of which a thin film will to be deposited, is inserted in the chamber 100. The chamber 100 is filled with the first gaseous precursor 74. The first precursor 74 may be continuously supplied into the chamber 100 through the inlets 102 and continuously evacuated 73 through the outlets 103 so that a desired pressure 75 (P1) is maintained in the chamber 100. The evacuation 73 may be implemented by any suitable means including, but not limited to, vacuum pumping.

In the embodiment shown in FIG. 1, the second precursor 70 is supplied to the surface of the substrate 1 through a nozzle 2. The nozzle 2 of some embodiments is slit-shaped. The gas flow 72 delivers the second precursor 70 to a localized area on the surface of the substrate 1.

In some embodiments, the substrate 1 is supported at a temperature favorable for the chemical reaction between the second precursor 70 and the surface of the substrate 100. The first precursor 74, the nozzle 2 and the internal walls of the chamber 100 may be supported at the temperature lower than that of the substrate 100 so that the second precursor 70 does not actively react with the first precursor 74 anywhere but on the surface of the substrate 1. The second precursor 70 reacts with the substrate resulting in the film deposition on the localized area on the surface of the wafer 1. Other products of this reaction and the residual amounts 72 of the precursor 70 are continuously evacuated from the chamber 100 through the outlets 103 together with the flow 73 of the first precursor.

The temperature of the substrate can be controlled by any suitable means known to those skilled in the art. In some embodiments, the substrate is supported by a substrate support with an electrode embedded therein. Providing a flow of current to the electrode causes the substrate support temperature to increase, thereby increasing the temperature of the substrate supported thereon.

The substrate can also be radially stationary or rotating. In some embodiments, the substrate is rotated in one or more of a continuous fashion and in discrete steps. When the substrate is rotated in discrete steps, it may be useful to rotate each step between individual deposition layers. In some embodiments, rotating the substrate during processing results in a more uniform deposition than stationary substrates.

The nozzle 2 is moved relative to the substrate 1 so that the precursor 70 is gradually applied to the whole surface of the substrate 1. It will be understood by those skilled in the art that movement of the nozzle 2 relative to the substrate 1 is implemented by one or more of motion of the nozzle 2, as arrow 50 shows, and by motion of the substrate 1, as arrow 51 shows.

The nozzle 2 is fed with the second precursor 70 through the inlet 71 so that the gas pressure 76 in the nozzle 2 is supported at a desired level P2 greater than P1. P1 may be in the range of about 1 Torr to about 50 Torr, or in the range of about 2 Torr to about 40 Torr and P2 may be in the range of about 100 Torr to 120 Torr, or in the range of about 101 Torr to about 110 Torr or in the range of about 102 Torr to about 103 Torr. In some cases P1 may be close to the atmospheric pressure (760 Torr) and P2 may be in the range of about 800 Torr to about 2000 Torr.

The Figures show the nozzle 2 without within the chamber without connection to a gas source. This is purely for ease of understanding the drawings and it will be understood by those skilled in the art that the nozzle is in fluid communication with a gas source through some connection. Suitable connections include, but are not limited to, fixed and flexible piping. In some embodiments, the nozzle 2 is connected to the precursor source through a flexible pipe or tube leaving the nozzle movement unhindered. In some embodiments, the substrate support holds the substrate in a substantially fixed position. As used in this specification and the appended claims, the term “substantially fixed” means that there is no intentional movement of the substrate by the substrate support. The possibility of inadvertent or incidental movement (e.g., from vibrations) is understood to be possible.

FIG. 2 shows a top view of the substrate 1 and slit-shaped nozzle 2. During one deposition cycle, the slit-shaped nozzle 2 passes over the substrate from left to right so that the second precursor 70 is applied to the whole surface of the substrate 1. The movement of the nozzle 2 relative to the substrate 1 is implemented by the motion of the nozzle 2, as the arrows 50 show, and/or by the motion of the substrate 1, as the arrow 51 shows.

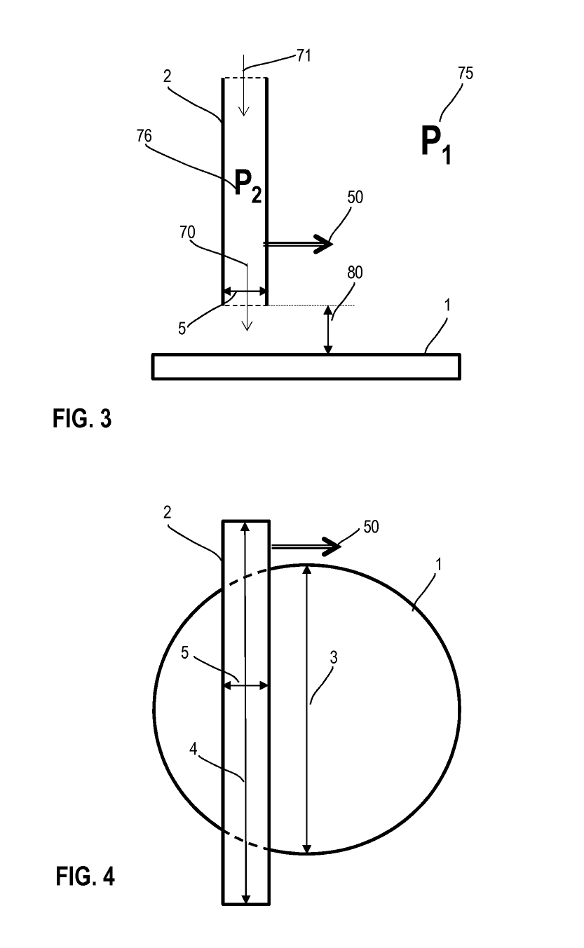

The body of the slit-shaped nozzle 2 may have external sidewalls 20, internal sidewalls 21 and the feeding slit 22. The slit-shaped nozzles may have any shape and design that allows localized delivery of precursors to the substrate surface. For the sake of simplicity, the further description is illustrated by figures on which the slit-shaped nozzle 2 is depicted as a rectangle (see FIGS. 3-4). The movement of the nozzle 2 relative to the substrate 1 is shown by arrow 50 that implies that this movement may also be implemented by moving the substrate 1. Gas pressure 75 (P1) in the deposition chamber, gas pressure 76 (P2) in the nozzle, the distance 90 from tip of the nozzle 2 to the surface of the substrate 1 and the width 5 of the nozzle may be chosen to provide the best performance of the CVD process and the resulting film quality. In some embodiments, the distance 90 from tip of the nozzle 2 to the surface of the substrate 1 is in the range of about 0.1 mm to about 15 mm, or in the range of about 0.2 mm to about 13 mm, or in the range of about 0.3 mm to about 10 mm. In some embodiments, the width 5 of the nozzle is in the range of about 0.3 mm to about 10 mm, or in the range of about 0.4 mm to about 7.5 mm or in the range of about 0.5 mm to about 5 mm. As FIG. 4 shows the length 4 of the slit-shaped nozzle 2 in some embodiments is greater than the length 3 of the substrate 1 so the second precursor 70 would be delivered uniformly to the whole surface of the substrate 1 and the edges of the substrate would not disturb the flow of the second precursor 70. Both the first precursor 74 and the second precursor 70 may originate self-limiting surface reactions on the substrate 1 like in ALD processes.

Some embodiments of the invention provide more uniform gas flow than in a conventional ALD reaction chamber. One or more embodiments provide a more equalized distribution of gases (i.e., more uniform distribution of gases) inside of a nozzle than in a conventional ALD reaction chamber. In one or more embodiments, the film deposited is more uniform than a film deposited in a conventional ALD chamber. In some embodiments, there is one or more of more uniform gas flow, more equalized distribution of gases inside the nozzle and more uniform film deposition compared to a convention ALD reaction chamber and process.

Some embodiments are more effective at controlling the film deposition process compared to a conventional. Parameters which may affect the film deposition process include, but are not limited to, the size of the nozzle, the distance between the nozzle and the substrate, the gas pressures in the chamber and in the nozzle, the flow of the first precursor supply and evacuation and the speed of nozzle movement relative to the substrate. Adjusting these parameters, one may achieve better film quality for a given choice of precursors.

The movement speed 50 of the nozzle 2 may be easily chosen to supply to the substrate 1 the amount of the second precursor 70 sufficient for only one atomic layer deposition or even less. In some embodiments, the nozzle 2 moves, relative to the substrate, at a speed in the range of about 10 mm/sec to about 1 m/sec, or in the range of about 20 mm/sec to about 800 mm/sec, or in the range of about 30 mm/sec to about 500 mm/sec, or in the range of about 30 mm/sec to about 300 mm/sec, or in the range of about 50 mm/sec to about 100 mm/sec. The speed at which the nozzle moves relative to the substrate may be dependent on a number of factors including, but not limited to, concentration of the gas, the rate of the chemical reaction and the rate at which excess gas can be removed from the chamber. Without being bound by any particular theory of operation, it is believed that higher movement rates may help in the evacuation of excess gases due to perturbation from the elongate nozzle movement.

Embodiments of the invention allow for the elimination of ineffective cycles of conventional ALD processes. For examples, removing non-reacted precursors and by-products and re-introducing the precursors can be eliminated. Therefore, the speed at which equivalent substrates (e.g., size and material) can be equivalently processed (e.g., same chemistry and film thickness) may be greater than using conventional ALD equipment.

One deposition cycle corresponds to one pass of the nozzle across the substrate. Without being bound by any particular theory of operation, during a cycle, a transient deposition happens only over a localized area on the surface of a substrate. Over an extended time, other areas of the substrate remain exposed to the first precursor. This helps to complete surface reaction between the first precursor and the products of the preceding reaction of the second precursor on the substrate surface. In the result, the compositional and structural quality of the deposited film may be improved while the contamination with byproducts may be reduced compared to conventional ALD.

Additionally, one or more embodiments of the invention may be operated at high pressures, such as near-atmospheric or even above atmospheric. Operation at such high pressures can result in ultra-fast deposition processes.

In some embodiments, the consumption of the second precursor is significantly reduced and consequently makes the deposition less expensive and more environmentally friendly.

The shape of the chamber 100 can be any suitable shape including, but not limited to, round, ellipsoid and rectangular. The shape of the chamber 100 may have an impact on the uniformity of the flow of the gases within the chamber. In some embodiments, the chamber 100 has a rectangular shape and has a greater uniformity of precursor flows and distributions along the feeding slit-shaped nozzle in the chamber.

To describe the operation of the processing chamber 100, the deposition of an example high-k dielectric, such as HfO₂ films, is described. It will be understood by those skilled in the art that the chemistry and reaction condition described are merely exemplary and that other chemistries and conditions can be employed. Water vapor (H₂O) can be used as the first precursor and is introduced into the chamber and supported at pressure P1. To prevent condensation, the internal walls of the chamber and the external surface of the nozzle may be maintained at elevated temperature such as 120° C. A suitable hafnium precursor, such as hafnium tetrachloride (HfCl₄), is used as the second precursor. The temperature of a silicon substrate can be maintained at 250° C., a temperature suitable for the ALD reactions involved. Initial exposure of the substrate to the first precursor leads to a chemosorption of H₂O on the wafer surface. The second precursor flowing from the nozzle supplies HfCl₄ to the hot wafer surface. As a result of the following chemical reaction occurs on the wafer surface

2H₂O+HfCl₄→HfO₂+4HCl

A layer of HfO₂ is former and volatile HCl is removed from the reactor with continues H₂O flow. The film deposition is controlled by the localized/limited supply of HfCl₄ (the second precursor) to the substrate surface.

Although the chamber of FIG. 1 has been shown and described with a single gas source in communication with the nozzle 2, there can be more than one gas source. For example, the nozzle 2 may in fluid communication with a manifold dedicated to nozzle 2, in which different precursors and mixtures of precursors can be employed. This allows the second precursor to be changed with relative ease compared to completely purging the process chamber.

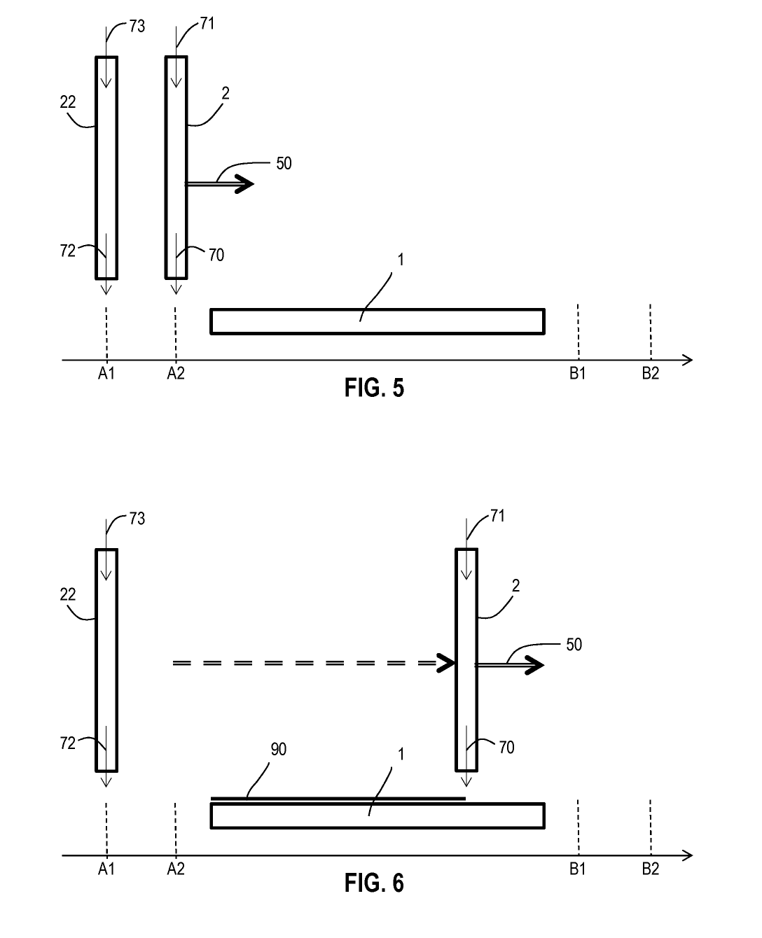

Another ALD-specific embodiment of the invention is illustrated in FIGS. 5-12. There are several slit-shaped nozzles which are used to deliver all active precursors to the substrate 1 surface. These nozzles can independently move above the surface of the substrate. The number of slit-shaped nozzles may be equal to the number of active precursors required for deposition. For simplicity, the embodiment is described considering a case of deposition that uses two precursors, but it will be understood by those skilled in the art that more than two precursors can be used.

The chamber is filled with an inert gas such as nitrogen or argon. The inert gas may be continuously supplied into the chamber through inlets and continuously evacuated through the outlets so that the pressure P1 is maintained in the chamber. P1 may be essentially low and correspond to a partial vacuum. The first precursor 70 is supplied into a slit-shaped nozzle 2 through the inlet 71. The second precursor 72 is supplied into a slit-shaped nozzle 22 through the inlet 73.

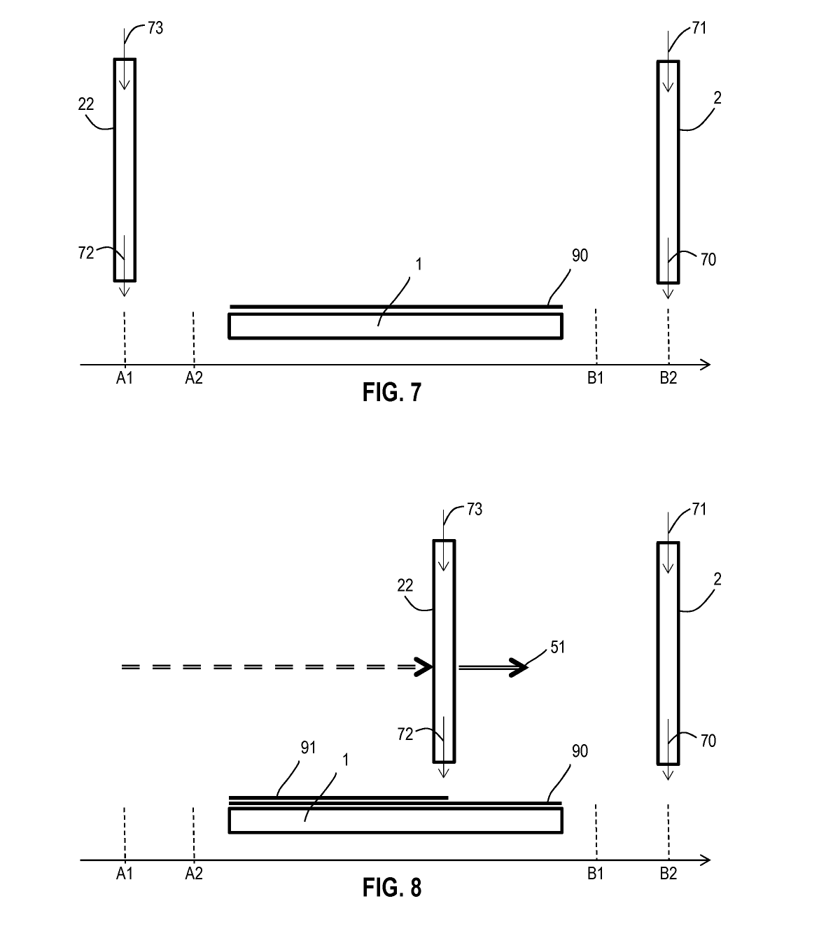

Initially, the slit-shaped nozzles 71 and 73 have positions A2 and A1 outside of the substrate 1 (FIG. 5). Deposition starts with moving the slit-shaped nozzle 2 in the chamber across the substrate 1 (FIG. 6). The gas flow delivers the first precursor 70 to a localized area on the surface of the substrate 1. The substrate 1 may be supported at a temperature favorable for the chemical reaction between the precursors and the substrate. The first precursor 70 reacts with the substrate 1 resulting in the atomic layer 90 deposition on the said localized area on the substrate surface. This may be a self-limiting ALD-type surface reaction. The products of this reaction and the residual amount of the precursor 70 are continuously evacuated from the chamber. The slit-shaped nozzle 2 is moving relative to the substrate 1 so that the precursor 70 is gradually applied to the whole surface of the substrate 1. The movement of the nozzle 2 relative to the substrate 1 is implemented by the motion of the nozzle 2, as the arrow 50 shows. After passing the substrate 1, the nozzle 2 stops outside of the wafer 1 at the position B2 (FIG. 7).

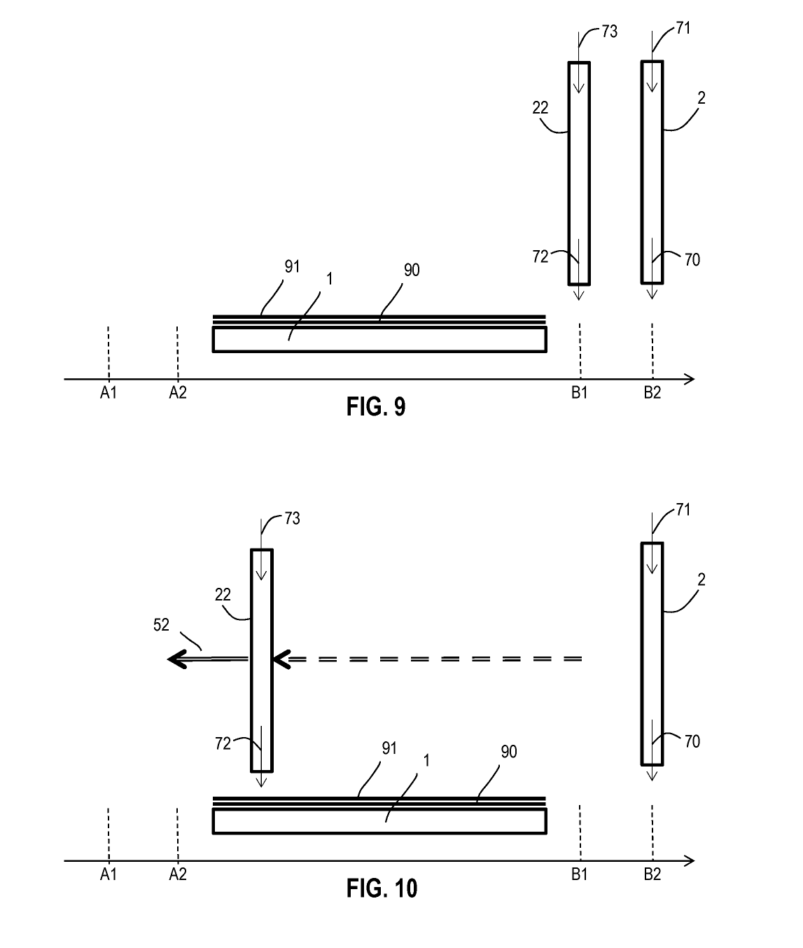

This follows by the movement of the slit-shaped nozzle 22 in the chamber across the substrate 1 (FIG. 8). The gas flow delivers the second precursor 72 to a localized area on the surface of the substrate 1. The second precursor 72 reacts with the atomic layer 90 formed by the first precursor. This results in depositing another atomic layer 91. The reaction of the second precursor 72 with the atomic layer 90 may also be a self-limiting ALD-type surface reaction. The products of this reaction and the residual amount of the precursor 72 are continuously evacuated from the chamber. The slit-shaped nozzle 22 is moving relative to the substrate 1 so that the precursor 72 is gradually applied to the whole surface of the substrate 1. After passing the substrate 1, the nozzle 22 stops outside the wafer at the position B1 (FIG. 9).

Next, the nozzle 22 is moving back to a position A1 (FIG. 10). During the move, it may continue delivering the precursor 72 to the substrate surface ensuring the completeness of the reaction between the atomic layer 90 and the precursor 72. Such a repeated application of a precursor may provide more uniform and stable films having less impurity contamination. This completes the first deposition cycle.

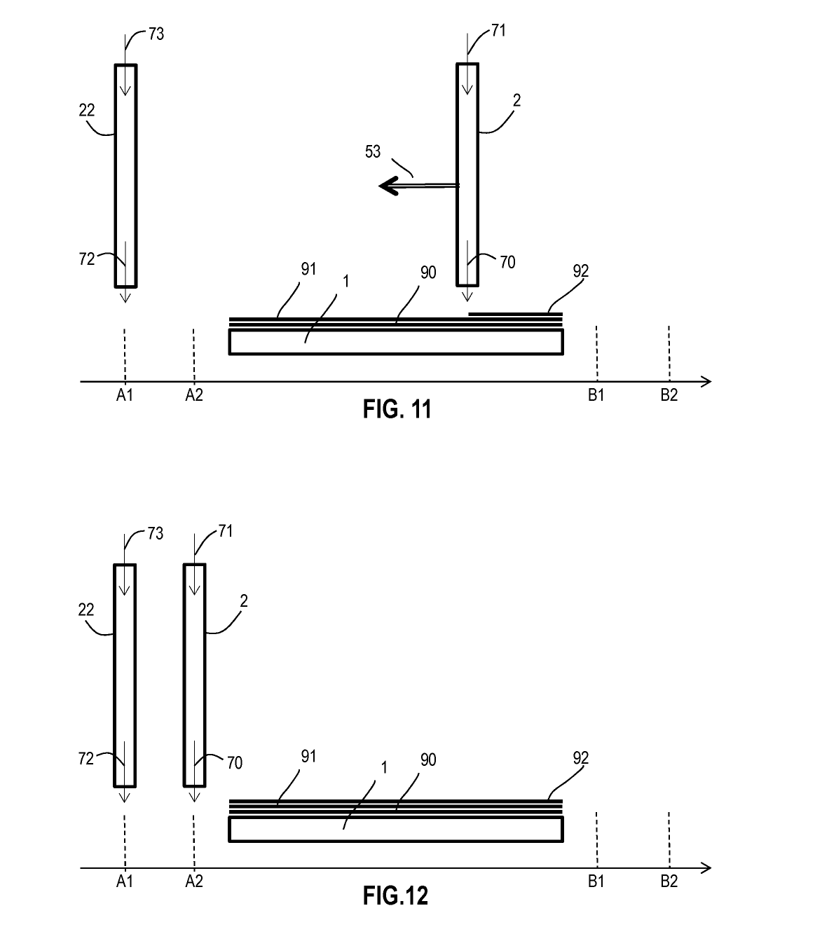

The second deposition cycle starts with the movement of the nozzle 2 from position B2 back to position A2 (FIG. 11). The nozzle 2 supplies the first precursor 70 to the surface of the substrate 1 resulting in the reaction of the precursor 70 with the atomic layer 91 and the film growth that is schematically shown as the atomic layer 92. The nozzle 2 arrives to the initial position A2 (FIG. 12).

Repeating passes of nozzles 2 and 22 over the substrate will increase the thickness of the growing film with the atomic level of control.

In an additional embodiment, again referring to FIG. 5, a mixed film can be deposited. A first pressure of a first precursor gas (e.g., water vapor) is maintained in the processing chamber. Slit 2 contains a second precursor and slit 22 contains a third precursor. Slit 2 can move recursively over the substrate 1, as in the embodiment shown in FIG. 1. Each pass over the substrate 1 would result in deposition of a layer on the substrate resulting from the alternating reactions of the first precursor and the second precursor.

At some point during the process, when the nozzle 2 is in the B1 or B2 position, the nozzle 22 can move across the surface of the substrate. Each pass of this nozzle provides a third precursor to the substrate surface and deposits a different layer. The nozzle 22 can be moved recursively any number of cycles to deposit different thicknesses of the second film. Once the nozzle 22 has returned to the A1 or A2 position, the first nozzle 2 can be moved recursively over the substrate 1 to deposit additional films. Thus, a mixed film can be easily deposited on the substrate.

Some embodiments of the invention have the unique capability of forming ALD films with deposition control on sub-atomic level. The capabilities for controlling the composition of the deposited film are widened from conventional ALD because all of the precursors can be supplied independently. In some embodiments, low pressure in the chamber accelerates the removal of the precursors and further increases the process throughput. Additionally, in one or more embodiments, the decomposition and/or removal of reaction by-products is accelerated which may improve the purity of the resulting films.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. The remotely formed plasma can be flowed into the chamber through one or more of the nozzles.

In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not required. Indeed, other embodiments relate to deposition processes under very mild conditions without a plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool”, “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

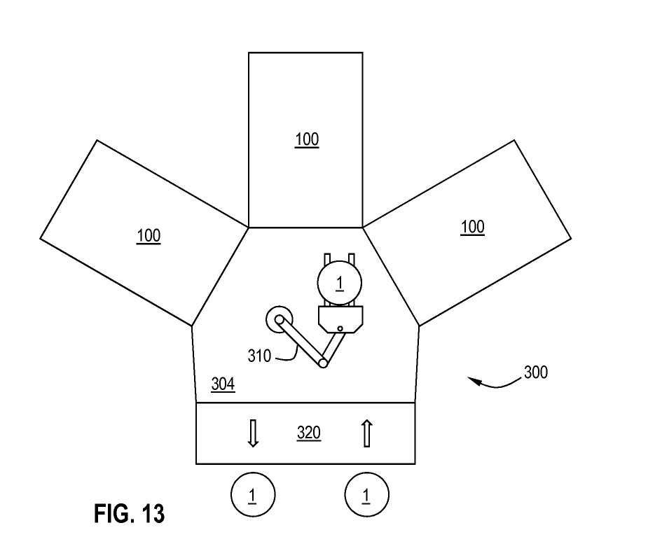

Additional embodiments of the invention are directed to cluster tools comprising at least one atomic layer deposition system described. The cluster tool has a central portion with one or more branches extending therefrom. The branches being deposition, or processing, apparatuses. The central portion of the cluster tool may include at least one robot arm capable of moving substrates from a load lock chamber into the processing chamber and back to the load lock chamber after processing. Referring to FIG. 13, an illustrative cluster tool 300 includes a central transfer chamber 304 generally including a multi-substrate robot 310 which is capable of transferring a plurality of substrates in and out of the load lock chamber 320 and the various process chambers 100. Although the cluster tool 300 is shown with three processing chambers 100, it will be understood by those skilled in the art that there can be more or less than 3 processing chambers. Additionally, the processing chambers can be for different types (e.g., ALD, CVD, PVD) of substrate processing techniques.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A deposition system comprising:
a processing chamber;
a gas inlet to provide a first gas at a first pressure to the processing chamber;
a substrate support disposed within the processing chamber to support a substrate; and
an elongate nozzle to provide a second gas at a second pressure to the processing chamber, wherein the elongate nozzle is adjacent the substrate support, the second pressure is higher than the first pressure, and at least one of the elongate nozzle and the substrate support is movable relative to the other one of the elongate nozzle and the substrate support.

2. The system of claim 1, wherein, when a substrate is present, movement of the elongate nozzle covers the entire substrate.

3. The system of claim 1, wherein, when a substrate is present, the elongate nozzle has a width greater than the substrate.

4. The system of claim 1, wherein the substrate support is in a substantially fixed position and the elongate nozzle moves.

5. The system of claim 1, wherein the elongate nozzle is in a substantially fixed position and the substrate support moves.

6. The system of claim 1, wherein the substrate support comprises a heater.

7. The system of claim 1, wherein the substrate support rotates either continuously or in discrete steps.

8. The system of claim 1, wherein, when a substrate is present, the elongate nozzle is in the range of about 0.5 mm to about 10 mm from the substrate.

9. The system of claim 1, wherein the elongate nozzle moves relative to the substrate support at a speed in the range of about 10 mm/sec to about 1 m/sec.

10. The system of claim 1, wherein the first gas and the second gas are reactive gases.

11. The system of claim 1, further comprising a second elongate nozzle to provide a third gas at a pressure greater than the first pressure to the processing chamber.

12. The system of claim 11, wherein the substrate support is in a substantially fixed position and each elongate nozzle is independently movable.

13. The system of claim 11, wherein the first gas is an inert gas and each of the second gas and third gas are different reactive gases.

14. The system of claim 11, wherein each of the first gas, the second gas and the third gas are different reactive gases.

15. A cluster tool comprising a central transfer chamber and the atomic layer deposition system of claim 1.

16. An atomic layer deposition system comprising:
a processing chamber;
a gas inlet to provide a first gas at a first pressure to the processing chamber;
a substrate support disposed within the processing chamber to support a substrate in a substantially fixed position;
a first elongate nozzle to provide a second gas at a second pressure toward the substrate support in the processing chamber, the first elongate nozzle movable relative to the substrate support, the second pressure higher than the first pressure; and
a second elongate nozzle to provide a third gas toward the substrate support in the processing chamber, the second elongate nozzle independently movable relative to the substrate support and the first elongate nozzle.

17. A method of processing a substrate in a processing chamber, the method comprising:
supporting the substrate on a substrate support;
exposing the substrate to a first gas in the processing chamber; and
moving a first elongate nozzle relative to and above the substrate support, the first elongate nozzle providing a second gas to the processing chamber toward the substrate, wherein the first elongate nozzle moves reciprocally relative to the substrate so that portions of the substrate under the first elongate nozzle are exposed to the second gas and portions of the substrate not under the first elongate nozzle are exposed to the first gas.

18. The method of claim 17, further comprising moving a second elongate nozzle relative to and above the substrate support, the second elongate nozzle providing a third gas to the processing chamber toward the substrate, the second elongate nozzle adjacent to the first elongate nozzle and independently movable relative to the first elongate nozzle and the substrate.

19. The method of claim 18, wherein the first gas is an inert gas and each of the second gas and third gas are different reactive gases.

20. The method of claim 18, wherein each of the first gas, the second gas and the third gas are different reactive gases.
